(19) United States
(12) Patent Application Publication
(10) Pub. No.: US 2025/0204012 A1
(43) Pub. Date: Jun. 19, 2025

(54) SEMICONDUCTOR DEVICE AND METHOD OF MANUFACTURING THE SAME

(71) Applicant: Renesas Electronics Corporation, Tokyo (JP)

(72) Inventor: Shotaro KUDO, Tokyo (JP)

(21) Appl. No.: 18/926,491

(22) Filed: Oct. 25, 2024

(30) Foreign Application Priority Data
Dec. 14, 2023 (JP) 2023-211271

(51) Int. Cl. H01L 29/49; H01L 29/45; H01L 29/66; H01L 29/739

(52) U.S. Cl. CPC H10D 64/661; H10D 12/038; H10D 12/481; H10D 62/83; H10D 64/62

(57) ABSTRACT

A semiconductor device includes an insulating film, and a polysilicon film formed on the insulating film. The semiconductor device includes, in plan view, a first region including a first semiconductor element formed of the polysilicon film, and a second region including a second semiconductor element. A first contact hole formed in the first region extends through the polysilicon film. An ohmic contact is formed between a metal embedded in the first contact hole and the polysilicon film on a side surface of the first contact hole.

### CROSS-REFERENCE TO RELATED APPLICATIONS

The disclosure of Japanese Patent Application No. 2023-211271 filed on Dec. 14, 2023 including the specification, drawings and abstract is incorporated herein by reference in its entirety.

### BACKGROUND

The present invention relates to a semiconductor device including a polysilicon film and a method of manufacturing the same.

There is a disclosed technique listed below.
[Patent Document 1] Japanese Unexamined Patent Application Publication No. H07-153920

Paten Document 1 discloses a semiconductor device including a temperature sensing diode formed of a polysilicon film.

### SUMMARY

There is a problem in that it is difficult to simultaneously process a contact in a semiconductor element formed of a thin polysilicon film and a contact in a semiconductor element such as a transistor.

Other objects and novel features will become apparent from the description of the present specification and the accompanying drawings.

According to one embodiment, a semiconductor device includes an insulating film, and a polysilicon film formed on the insulating film. The semiconductor device includes, in plan view, a first region including a first semiconductor element formed of the polysilicon film, and a second region including a second semiconductor element. A first contact hole formed in the first region extends through the polysilicon film, and an ohmic contact is formed between a metal embedded in the first contact hole and the polysilicon film on a side surface of the first contact hole.

According to one embodiment, in a method of manufacturing a semiconductor device, the semiconductor device includes an insulating film and a polysilicon film formed on the insulating film. The semiconductor device includes, in plan view, a first region including a first semiconductor element formed of the polysilicon film, and a second region including a second semiconductor element. The method of manufacturing the semiconductor device includes the steps of forming a first contact hole extending through the polysilicon film in the first region and forming a second contact hole in the second region, and performing oblique ion implantation so that an ion implantation region is formed at a cross section of the polysilicon film crossed by the first contact hole.

According to the one embodiment, a semiconductor device and a method of manufacturing the semiconductor device can be provided in which simultaneous processing of a contact in a first semiconductor element formed of a thin polysilicon film and a contact in a second semiconductor element is ensured.

### BRIEF DESCRIPTION OF THE DRAWINGS

FIG. 1 is a circuit diagram illustrating a configuration of a semiconductor device according to a first comparative example.

FIG. 2 is an explanatory diagram illustrating an example of a layout of the semiconductor device according to the first comparative example. FIG. 3 is an explanatory diagram of a method of manufacturing the semiconductor device according to the first comparative example.

FIG. 4 is an explanatory diagram of a method of manufacturing a semiconductor device according to a second comparative example.

FIG. 5 is a schematic cross-sectional view of a semiconductor device according to a first embodiment.

FIG. 6 is an explanatory diagram of a method of manufacturing the semiconductor device according to the first embodiment.

FIG. 7 is an explanatory diagram of a first configuration example of the semiconductor device according to the first embodiment.

FIG. 8 is an explanatory diagram of a second configuration example of the semiconductor device according to the first embodiment.

FIG. 9 is a graph illustrating electrical characteristics of a temperature sensing diode according to the first embodiment.

FIG. 10 is a set of graphs illustrating the variation in electrical characteristics of the temperature sensing diode according to the first embodiment.

### DETAILED DESCRIPTION

For clarity of explanation, the following description and drawings have been omitted and simplified as appropriate. In each drawing, the same elements are denoted by the same reference numerals, and duplicated descriptions are omitted as necessary.

### Examination Leading to Embodiment

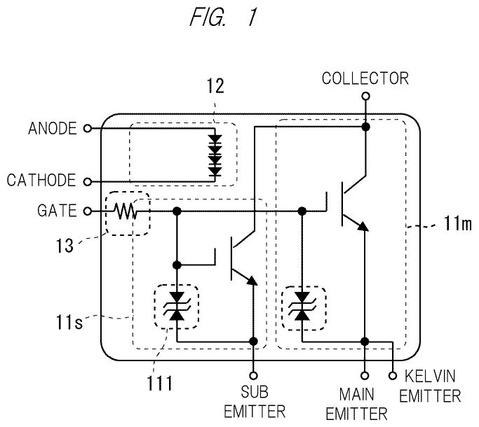

FIG. 1 is an equivalent circuit diagram of a semiconductor device 10 according to a comparative example. The semiconductor device 10 includes a main IGBT 11m, a sub IGBT 11s, a temperature sensing diode 12, and a built-in gate resistor 13. The main IGBT 11m and the sub IGBT 11s include respective protective diodes 111.

A collector of the main IGBT 11m and a collector of the sub IGBT 11s are connected to each other. An emitter of the main IGBT 11m is connected to a main emitter terminal, and an emitter of the sub IGBT 11s is connected to a sub emitter terminal. The main emitter terminal is connected to a Kelvin emitter terminal. In a case where the main IGBT 11m and the sub IGBT 11s are not distinguished from each other, the main IGBT 11m and the sub IGBT 11s may simply be referred to as IGBT 11.

The protective diode 111 is arranged between the gate and the emitter of the IGBT 11. The protective diode 111 diverts the instantaneously high voltage (surge) generated between the gate and the emitter of the IGBT 11 to protect a gate insulating film of the IGBT 11.

The temperature sensing diode 12 is used to sense the temperature of the semiconductor device 10. The temperature is sensed by utilizing the temperature dependency of a forward voltage (VF) of the temperature sensing diode 12. The temperature sensing diode 12 is formed of a polysilicon film. Four diode elements are arranged in series between an anode terminal and a cathode terminal.

The built-in gate resistor 13 adjusts the rise and fall speed of the gate voltage of the IGBT 11.

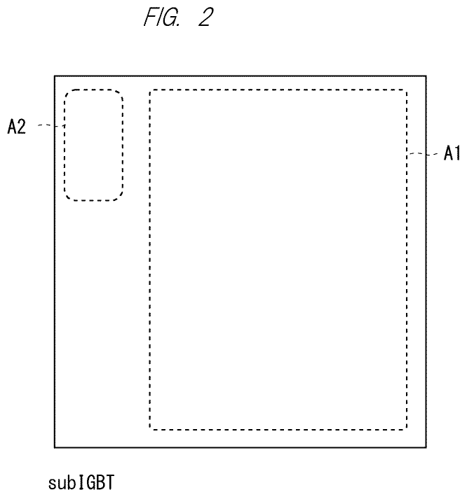

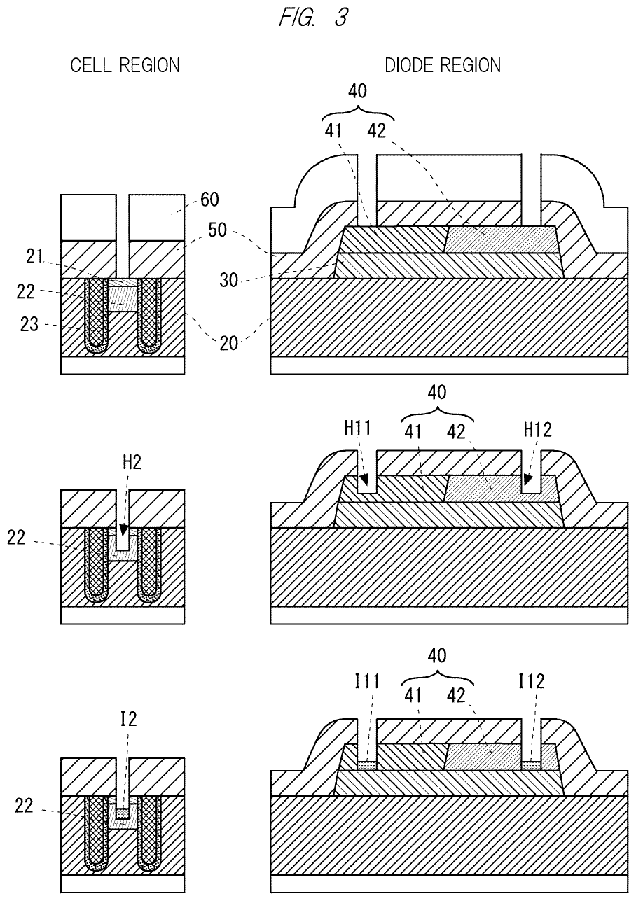

When the semiconductor device 10 is viewed in a plan view, the IGBT 11, the temperature sensing diode 12, and the built-in gate resistor 13 are arranged in different regions separate from each other. In particular, the region in which the temperature sensing diode 12 is arranged (also referred to as a diode region) is different from the region in which the IGBT 11 is arranged (also referred to as a cell region). FIG. 2 illustrates an arrangement example of a diode region A1 and a cell region A2.

Referring to FIG. 3, a method of manufacturing the semiconductor device according to a first comparative example will be described.

Referring to the upper diagrams, the diagram on the left illustrates a schematic cross-sectional view of the cell region, and the diagram on the right illustrates a schematic cross-sectional view of the diode region. Referring to the diagram on the left, an n-type semiconductor region 21, a p-type semiconductor region 22, and a trench gate electrode 23 are formed in a silicon substrate 20. The trench gate electrode is embedded in the trench via the gate insulating film. An oxide film 50 is formed on the silicon substrate 20 and the oxide film 50 is covered with a resist 60. A pattern is formed on the resist 60 by photolithography, and the oxide film 50 is etched using the resist pattern as an etching mask, thereby forming an opening in the oxide film 50. The oxide film 50 may be, for example, a Tetraethyl orthosilicate (TEOS) film.

Referring to the diagram on the right, an insulating film 30 is formed on the silicon substrate 20. A polysilicon film 40 is formed on the insulating film 30. By performing the ion implantation, a p− type semiconductor region 41 and an n+ type semiconductor region 42 are formed in the polysilicon film. For the p-type semiconductor region 41, for example, boron is implanted. The oxide film 50 is formed on the polysilicon film and the oxide film 50 is covered with the resist 60. A pattern is formed on the resist 60 by photolithography, and the oxide film 50 is etched using the resist pattern as an etching mask, thereby forming openings in the oxide film 50.

Referring to the middle diagrams, the silicon substrate 20 exposed at the opening in the oxide film 50 is etched (e.g., dry etching) to form a contact hole H2 in the cell region, and contact holes H11 and H12 are formed in the diode region. Referring to the diagram on the left, the contact hole H2 reaches the p-type semiconductor region 22. Referring to the diagram on the right, the contact holes H11 and H12 do not extend through the polysilicon film 40 due to the sufficient thickness of the polysilicon film 40.

Referring to the lower diagrams, by ion plantation, a p+ type ion implantation region I2 is formed in the p-type semiconductor region 22 in the cell region, and p+ type ion implantation regions I11 and I12 are formed in the diode region. The ion implantation regions I11 and I12 are formed in the p-type semiconductor region 41 and the n+ type semiconductor region 42, respectively.

Accordingly, in the case where the contact hole H2 does not extend through the polysilicon film 40, the ion implantation region I11 can be formed simultaneously in the diode region with the ion implantation region I2 in the cell region, leading to an advantage of fewer number of steps.

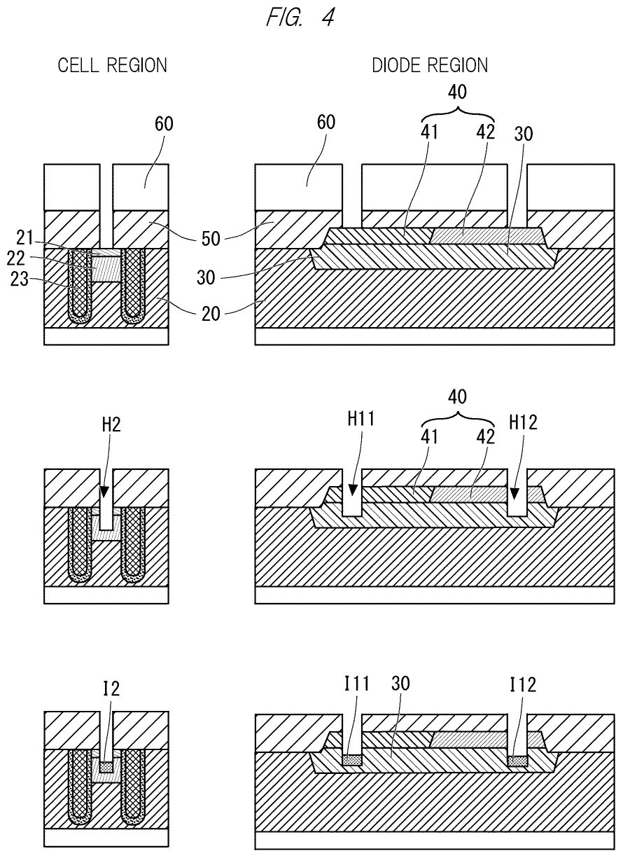

Referring to FIG. 4, a method of manufacturing a semiconductor device according to a second comparative example will be described. The polysilicon film 40 according to the second comparative example is thinner than the polysilicon film 40 according to the first comparative example. The upper, middle, and lower diagrams in FIG. 4 correspond to the upper, middle, and lower diagrams in FIG. 3, respectively. Referring to the middle diagrams, a contact hole H11 in the diode region extends through the polysilicon film 40. Referring to the lower diagrams, the implanted ions pass through the polysilicon film 40 and reach the insulating film 30. Due to this, the metal formed (embedded) in the contact hole H11 does not make an ohmic contact with the p− type semiconductor region 41 of the polysilicon film 40. In this case, the problem remains that the forward voltage (VF) of the temperature sensing diode formed of the polysilicon film 40 varies. To avoid the occurrence of VF variations, the step of forming the contact hole H2 in the cell region and the step of forming the contact hole H11 in the diode region are required to be separated, leading to the problem of an increased number of steps.

### First Embodiment

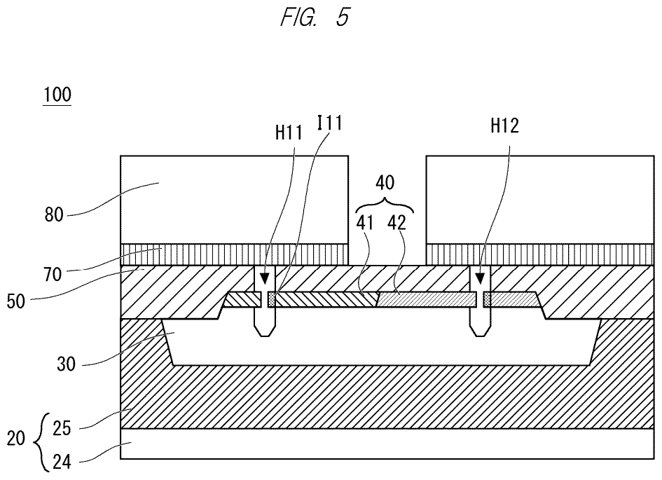

FIG. 5 illustrates a schematic cross-sectional view of a diode region of a semiconductor device 100 according to a first embodiment. As with the semiconductor device 10, the semiconductor device 100 further includes a cell region.

The semiconductor device 100 includes a silicon substrate 20, an insulating film 30, a polysilicon film 40, an oxide film 50, a barrier metal layer 70, and a wiring layer 80.

In the silicon substrate 20, a p-type well region 25 is formed on an n-type semiconductor region 24.

The insulating film 30 is formed on the well region 25. Specifically, the insulating film 30 includes an insulating region of a Local Oxidation of Silicon (LOCOS) structure formed on the well region 25, and a Low Pressure TetraEthyl Orthosilicate (LPTEOS) film formed on the insulating region.

The polysilicon film 40 is formed on the insulating film 30. The polysilicon film 40 includes a p− type semiconductor region 41 and an n+ type semiconductor region 42.

The oxide film 50 is formed on the polysilicon film 40. The oxide film 50 is, for example, a PETEOS film.

The barrier metal layer 70 is formed on the oxide film 50. The barrier metal layer 70 is composed of a material such as titanium-tungsten (TiW).

The wiring layer 80 is formed on the barrier metal film 70. The wiring layer 80 is composed of a material such as Al or Cu.

Contact holes H11 and H12 extending through the Oxide film 50 and the polysilicon film 40 are formed. A p+ type ion implantation region I11 is formed on the side wall of the p− type semiconductor region 41. The side wall indicates a cross section of the p− type semiconductor region 41, crossed by the contact hole H11. A metal such as tungsten (W) is formed (embedded) in the contact hole H11. A titanium nitride (TiN) film may be laid under the tungsten.

By forming the ion implantation region I11, the contact between the metal embedded in the contact hole 11 and the polysilicon film 40 becomes an ohmic contact. Note that, in the cell region, an ohmic contact is formed at the bottom surface of the contact hole H2.

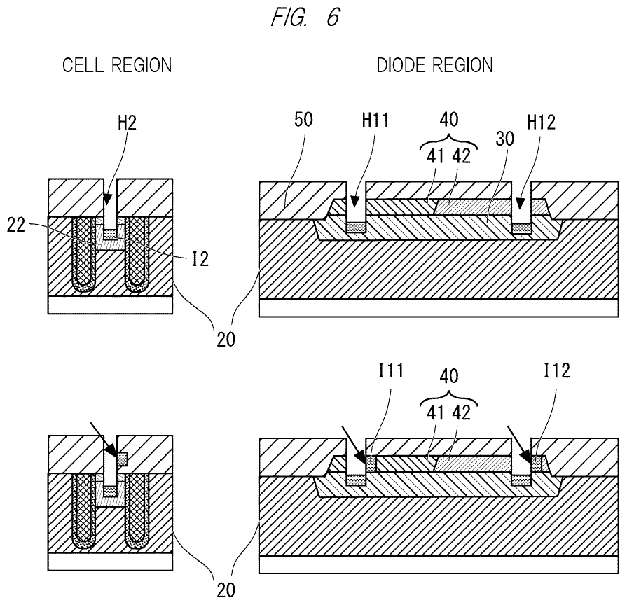

FIG. 6 is an explanatory diagram of a method of manufacturing the semiconductor device 100. The upper and lower diagrams in FIG. 6 correspond to the middle and lower diagrams in FIG. 4, respectively.

Referring to the upper diagrams in FIG. 6, the contact hole H2 is formed in the cell region, and the contact holes H11 and H12 are formed in the diode region. The contact holes H1 extend through the polysilicon film 40. By ion implantation, an ion implantation region 12 is formed in the p-type semiconductor region 22 in the cell region. At this point, ions are implanted into the insulating film 30 in the diode region.

Referring to the lower diagrams, ions are implanted in the direction indicated by the allows by oblique implantation. Accordingly, the ion implantation regions I11 and I12 are formed on the side walls of the polysilicon film 40 in the diode region. The side walls indicate cross sections of the polysilicon film 40, crossed by the contact holes H11 and H12. At this point, the aspect ratio (W/H) of the contact hole H2 may be appropriately set so that ions cannot be implanted into the silicon substrate 20 in the cell region. The aspect ratio is defined, for example, as the minimum value of the width of the contact hole relative to the depth of the contact hole.

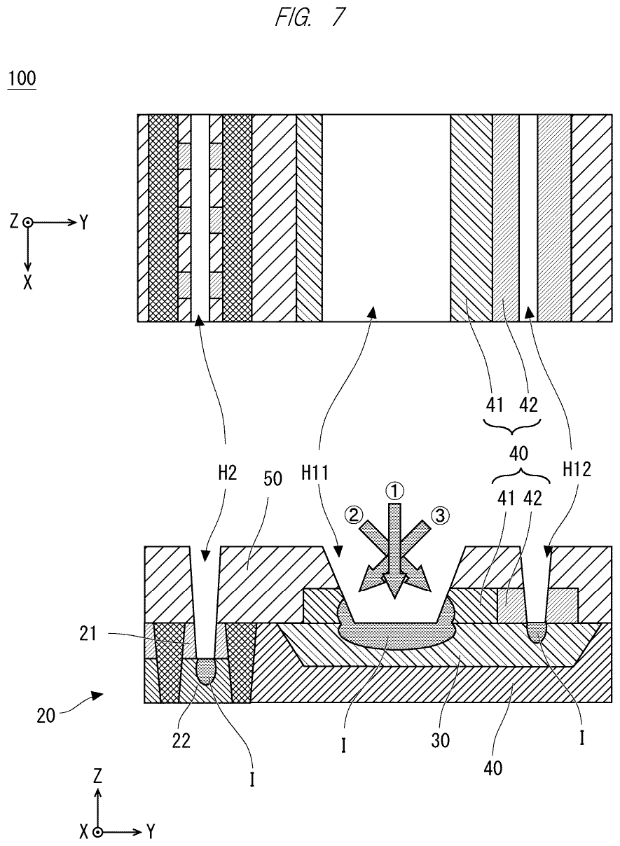

FIG. 7 is an explanatory diagram illustrating a first configuration example of the semiconductor device 100. The upper diagram is a schematic plan view of the semiconductor device 100, and the lower diagram is a schematic cross-sectional view. In the upper diagram, the illustration of the oxide film 50 is partly omitted. The thickness direction of the silicon substrate 20 is defined as the Z direction. The horizontal direction of the upper diagram is defined as the Y direction, and the vertical direction of the upper diagram is defined as the X direction.

The contact hole H11 extending through the p-type semiconductor region 41 of polysilicon is formed and the contact hole H12 extending through the n+ type semiconductor region 42 of polysilicon is formed, and the contact hole H2 extending through the n-type semiconductor region 21 in the cell region is formed. The contact holes H11, H12, and H2 extend in the X direction. The width of the contact hole 11 in the X direction is greater than the width of the contact hole H12 in the X direction. The width of the contact hole 11 in the X direction is greater than the width of the contact hole H2 in the X direction. That is, the aspect ratio of the contact hole H11 is smaller than the aspect ratio of the contact hole H2. The aspect ratio of the contact hole H11 is smaller than the aspect ratio of the contact hole H12.

When manufacturing the semiconductor device 100, ions are first implanted in the −Z direction as illustrated by “1”. Next, ions are implanted in a direction having a negative Z component and a positive Y component, as illustrated by “2”, and then ions are implanted in a direction having a negative Z component and a negative Y component, as illustrated by “3”. Accordingly, an ion implantation region I is formed. Ions are implanted into the side walls of the p− type semiconductor region 41 by “2” and “3”.

Ions are not implanted into the n-type semiconductor region 21 since the aspect ratio of the contact hole H2 is high. Also, ions are not implanted into the n+ type semiconductor region 42 of polysilicon since the aspect ratio of the contact hole H12 is high.

Also, the contact hole H11 may be formed so that the inclination angle of the side walls becomes gentle. An advantage of the side walls being gentle is that ions can be readily implanted into the side walls of the contact hole H11.

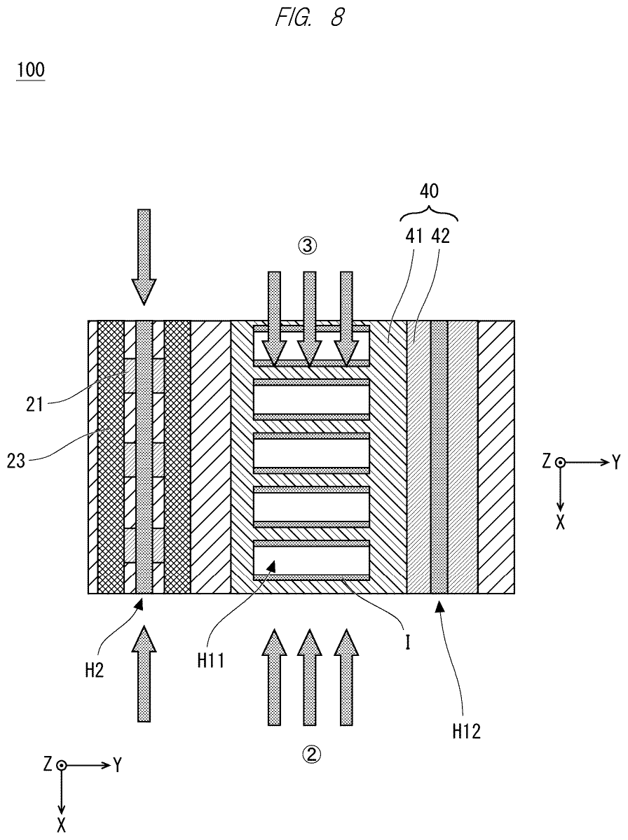

FIG. 8 is an explanatory diagram illustrating a second configuration example of the semiconductor device 100. The contact hole H11 extends in the Y direction, and the contact holes H2 and H12 extend in the X direction. In the step (2), ions are implanted in a direction having a negative Z component and a negative X component, and in the step (3), ions are implanted in a direction having a negative Z component and a positive X component. The step (1) may further be performed.

In the steps (2) and (3), ions are implanted into the side walls of the p− type semiconductor region 41. The contact holes H2 and H12 extend in the X direction; therefore, ions can be prevented from being implanted into the n-type semiconductor region 21 and the side wall of the n+ type semiconductor region 42.

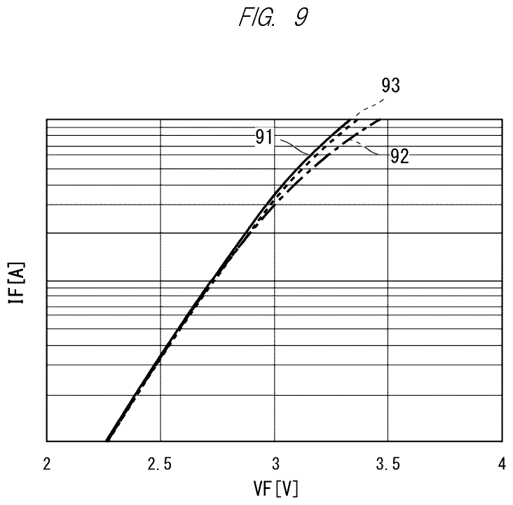

FIG. 9 is a illustrating graph the electrical characteristics of the temperature sensing diode. The horizontal axis represents the forward voltage, and the vertical axis represents the forward current. The curve 91 illustrates the electrical characteristics of the semiconductor device according to the first comparative example, the curve 92 illustrates the electrical characteristics of the semiconductor device according to the second comparative example, and the curve 93 illustrates the electrical characteristics of the semiconductor device 100 according to the first embodiment. In the second comparative example, the contact between the temperature sensing diode and the contact is not ohmic; therefore, the value of the forward current in the second comparative example is smaller than the value of the forward current in the first comparative example. It was found that the electrical characteristics equivalent to those of the first comparative example were observed when adopting the first embodiment.

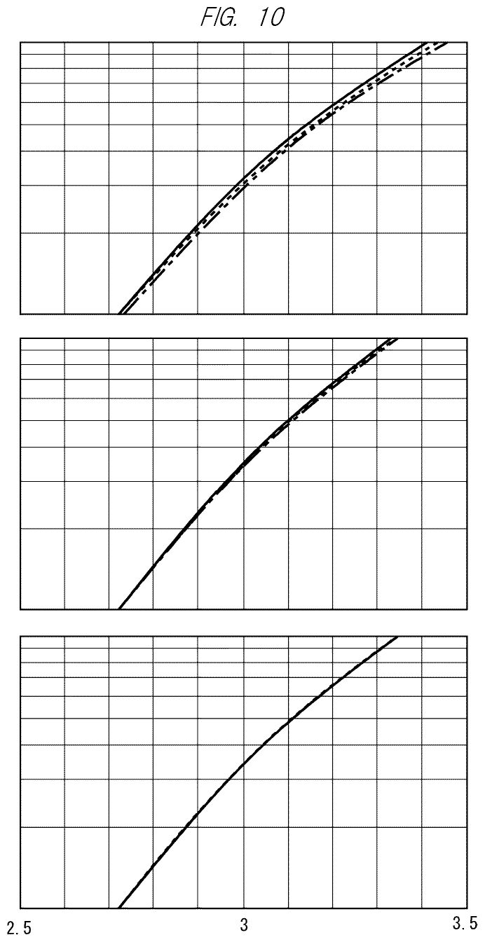

In FIG. 10, the upper graph illustrates the variation in electrical characteristics of the semiconductor device according to the second comparative example, the middle graph illustrates the variation in electrical characteristics of the semiconductor device according to the first comparative example, and the lower graph illustrates an overview of the variation in electrical characteristics of the semiconductor device according to the first embodiment. The horizontal axis represents the forward voltage and the vertical axis represents the forward current. Although the variation in electrical characteristics is greater in the second comparative example, the variation in electrical characteristics can be suppressed by adopting the first embodiment.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

For example, in the IGBT according to the above embodiment, the configuration in which the conductivity types (p-type or n-type) of the semiconductor substrate, the semiconductor layer, the diffusion layer (diffusion region), and the like, are inverted may be adopted. Therefore, when one of the n-type and p-type conductivity types is designated as a first conductivity type and the other as a second conductivity type, the first conductivity type can be set as p-type and the second conductivity type as n-type, or conversely, the first conductivity type can be set as n-type and the second conductivity type as p-type.

A semiconductor element formed of the polysilicon film 40 is not limited to a diode for temperature sensing, but the semiconductor element may also be a diode used for other purposes (e.g., a protection diode) or a fuse (e.g., an e-Fuse).

What is claimed is:

1. A semiconductor device comprising:
an insulating film; and
a polysilicon film formed on the insulating film,
wherein the semiconductor device includes, in plan view, a first region including a first semiconductor element formed of the polysilicon film, and a second region including a second semiconductor element,
wherein a first contact hole formed in the first region extends through the polysilicon film, and
wherein an ohmic contact is formed between a metal embedded in the first contact hole and the polysilicon film on a side surface of the first contact hole.

2. The semiconductor device according to claim 1,
wherein an ion implantation region is formed at a cross section of the polysilicon film crossed by the first contact hole.

3. The semiconductor device according to claim 2,
wherein an ohmic contact is formed at a bottom surface of the second contact hole between a metal embedded in the second contact hole formed in the second region and a substrate on which the second semiconductor element is formed.

4. The semiconductor device according to claim 3,
wherein an aspect ratio of the first contact hole is greater than an aspect ratio of the second contact hole.

5. The semiconductor device according to claim 3,
wherein the first contact hole extends in a first width direction perpendicular to a thickness direction of the substrate on which the second semiconductor element is formed, and
wherein the second contact hole extends in a second width direction perpendicular to the first width direction.

6. The semiconductor device according to claim 1,
wherein the semiconductor element is a temperature sensing diode.

7. A method of manufacturing a semiconductor device,
wherein the semiconductor device includes an insulating film and a polysilicon film formed on the insulating film, and
wherein the semiconductor device includes, in plan view, a first region including a first semiconductor element formed of the polysilicon film, and a second region including a second semiconductor element,
comprising the steps of:
forming a first contact hole extending through the polysilicon film in the first region and forming a second contact hole in the second region; and
performing oblique ion implantation so that an ion implantation region is formed at a cross section of the polysilicon film crossed by the first contact hole.
